(19) United States
(12) Patent Application Publication
(10) Pub. No.: US 2016/0113129 A1
(43) Pub. Date: Apr. 21, 2016

(54) Control Device

(71) Applicant: ZF FRIEDRICHSHAFEN AG, Friedrichshafen (DE)

(72) Inventor: Dirk Raschke, Auerbach (DE)

(21) Appl. No.: 14/891,271

(22) PCT Filed: Apr. 14, 2014
(86) PCT No.: PCT/EP2014/057461

§ 371 Date: Nov. 13, 2015

(30) Foreign Application Priority Data
May 15, 2013 (DE) 10 2013 208 984.8

(51) Int. Cl. H05K 5/00

(52) U.S. Cl. CPC H05K 5/0069; H05K 5/006

(57) ABSTRACT

The current embodiments provide a control device for a transmission of a vehicle. The control device may comprise a housing including a lower part and a housing cover, wherein the lower part of the housing has an assembly region on a first main surface. At least one attachment pin may be disposed in the assembly region, wherein the at least one attachment pin protrudes from the main surface and terminates inside the housing. The control device may comprise a printed circuit board disposed in the assembly region, the printed circuit board having at least one opening corresponding to the at least one attachment pin, wherein the at least one attachment pin passes through the at least one opening. At least one retaining washer disposed on the at least one attachment pin may be pressed towards the printed circuit board on the at least one attachment pin.

The current embodiments relate to a control device, in particular for a transmission of a vehicle.

Transmission controls for vehicle transmissions comprise a central electronic control unit, with which other control assemblies, such as sensors, valves, a connector for connecting to other vehicle systems and suchlike, can be connected. The central electronic control unit comprises electronic components, which are normally contained in a sealed installation space. With integrated transmission control devices, it is necessary to protect the electronic, or electrical components against the surrounding aggressive transmission fluid. For this, two metal covers are normally welded together, or two metal covers or a plastic housing are screwed or riveted to a metal cover.

Such transmission controls are typically exposed to environmental temperatures of 150° C. to −40° C. In order to dissipate these higher temperatures, the upper part of the housing occasionally exhibits cooling ribs through which fluid flows. Aside from the thermal load, vibration loads of up to 30 g normally occur. With these loads, the demands on the attachment of these interconnect devices, e.g. in removable attachments in the vehicle engine compartment, are significantly higher. In addition, it must also be ensured that the lowest possible expenditure regarding the material and manufacturing costs is implemented, and the quality as well as the service life of these sorts of electronic devices, with which contact can be appropriately established, e.g., via sockets disposed laterally on the lower part of the housing, are not compromised.

An attachment system is known from DE 10 2005 030 381 A1, which is herein incorporated by reference its entirety, with which a heat resistant and vibration cushioning rubber element, preferably an O-ring, is either loosely disposed, or disposed by means of injection, therein.

An assembly is known form the previously unpublished DE 10 2011 086 106.6, which is herein incorporated by reference in its entirety, with which a printed circuit board is attached between a lower part of the housing and a housing cover. Attachment pins extend thereby from the lower part of the housing through the printed circuit board and through the housing cover. Retaining washers are placed on the attachment pins outside of the housing, which rest against the housing cover, thus joining the two housing parts.

A disadvantage with the known embodiments is that, due to temperature fluctuations within the housing, tensions may develop within the printed circuit board.

An object of the current embodiments is to provide an assembly with which it is possible to attach a printed circuit board inside a housing, without tensions arising within the printed circuit board with the occurrence of temperature fluctuations.

This object is achieved with the assembly according to claim 1. Advantageous embodiments are the subject matter of dependent Claims.

The present embodiments create a control device, in particular for a transmission of a vehicle, wherein the control device has the following features:
a housing, comprising a lower part and a housing cover, wherein the lower part of the housing has an assembly region on a first main surface, in which a printed circuit board and at least one attachment pin can be disposed, which attachment pin protrudes from the main surface of the lower part of the housing and ends inside the housing,
a printed circuit board having at least one opening corresponding to the at least one attachment pin, wherein an attachment pin can pass through the at least one opening,
at least one retaining washer, which is designed to be pressed onto the at least one attachment pin, and to block a movement of the printed circuit board and the at least one retaining washer on the at least one attachment pin toward the free end of the attachment pin.

The orientation of the attachment pin is to be understood here, such that it extends perpendicular to the main surface of the housing base, i.e. in the direction of the z-axis.

The attachment pins can alternatively also be disposed on the housing cover.

The vehicle can be a motor vehicle, such as a passenger car or a truck, having a manual or automatic transmission. The control device assumes a central controlling function in the transmission control thereby. The control device, which implements an electronic control of the vehicle transmission, can also be referred to as an E-box, and be attached, as part of a mechatronic control module, for example, inside a transmission on a hydraulic control, or a circuit board, respectively, or on a transmission housing. The printed circuit board can be a circuit board. The lower part of the housing and/or the housing cover can be made of a metal or a plastic.

The lower part of the housing has a main surface that faces the printed circuit board when the control device is installed. An assembly region is disposed, for practical purposes, on the main surface of the lower part of the housing, which is covered by the printed circuit board when the control device is installed. The attachment pin of the printed circuit board is formed on the main surface of the lower part of the housing, e.g. adjacent to the assembly region, or in a peripheral region of the assembly region. The attachment pins can be formed as an integral part of the lower part of the housing. By way of example, two, three, four or more attachment means may be provided.

The printed circuit board has a hole or an opening, in particular a through hole. An opening profile of the through hole is designed thereby, in terms of the shape and size, such that a circumferential profile of the attachment pin can be received therein. By way of example, two, three, four or more through holes may be provided. A number of attachment pins can correspond to a number of through holes.

The circuit board can be secured to the attachment pins through force.

According to one embodiment, the lower part of the housing has at least two attachment pins, and the printed circuit board has exactly one hole, through which one of the at least two attachment pins passes in a transition fit. The other attachment pins are necessarily designed such that their cross-section is greater than the cross-section of the attachment pin. As a result, it is ensured that the attachment of the printed circuit board occurs on only one attachment pin. A thermal expansion of the printed circuit board in the direction of the x and y axes is possible at the other attachment pin or pins. In this manner, thermal tensions inside the printed circuit board are prevented.

Precisely one transition fit for the attachment of the printed circuit board on exactly one attachment pin is not necessary in another embodiment. It is also possible that the cross-sections of all of the attachment pins are smaller than the cross-sections of the associated attachment pins. Through the securing of the printed circuit board by means of the retaining washers on the attachment pins it is ensured that the printed circuit board has sufficient play for expansion for thermal tensions occurring for each hole allocated to an attachment pin.

In a further embodiment it is possible that at least one hole in the printed circuit board is elliptical or oval. For practical purposes, the length of a main axis of at least one elliptical or oval hole is greater than the greatest expansion of the retaining washer pressed onto the attachment pin passing through this hole.

The preferred embodiments, as well as further advantageous designs, shall be explained in greater detail based on the figures. Therein:

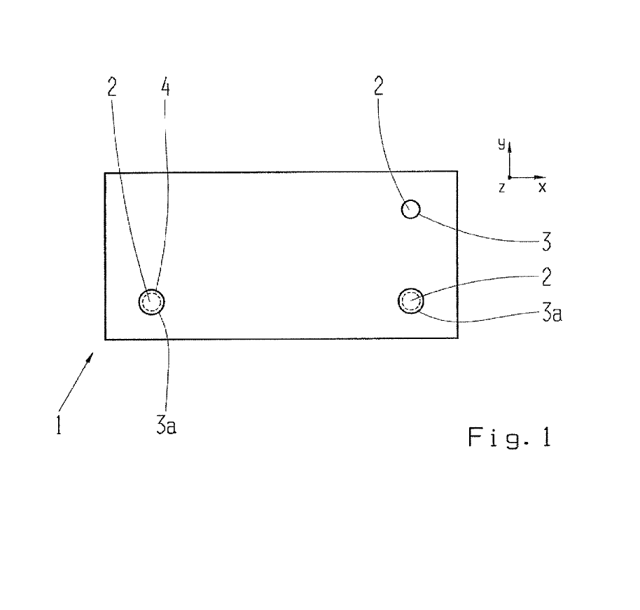

FIG. 1 shows, schematically, a printed circuit board having a first attachment means and, by way of example, three further attachment means.

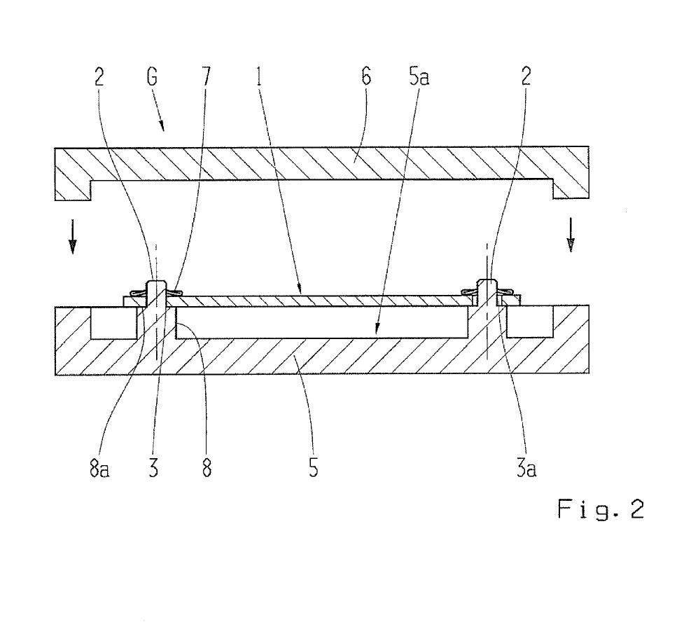

FIG. 2 shows, schematically, a sectional depiction through a lower part of the housing, having attachment means, a printed circuit board and securing means.

FIG. 1 shows, schematically, a printed circuit board from above. The printed circuit board 1 has a hole 3, 3a inside the printed circuit board 1. The holes 3, 3a are designed such that one hole 3 fits with a transition fit to an attachment pin 2 passing through the hole 3. The two other holes 3a, by way of example, are designed such that an intermediate space 4 exists between the attachment pin 2 and the edge of the hole 3a. This intermediate space 4 serves to accommodate expansions of the printed circuit board 1 along the x and y axes caused by thermal expansion. In FIG. 1, the attachment pin 2 is depicted as a circle drawn with a broken line. The corresponding hole 3 in the printed circuit board 1 is depicted as a circle drawn with a solid line.

FIG. 2 shows, schematically, a sectional depiction of a housing, with a lower part of the housing having attachment means, a printed circuit board and securing means, as well as a housing cover in a partially exploded depiction. The housing G has a lower part 5 and a housing cover 6 thereby. The housing cover 6 is applied to the lower part 5 in the direction of the arrow, and connected thereto using suitable joining techniques. These can comprise adhesive, solder or welded connections, as well as clamping connections. Seals (not shown) may be provided between the lower part 5 of the housing and the housing cover 6.

The lower part 5 of the housing has attachment pins 2 on its main surface 5a. These attachment pins 2 are designed substantially as domes, and extend vertically away from the main surface 5a of the lower part 5 of the housing, toward the housing cover 6.

The attachment pins 2 pass through the holes 3, 3a formed in the printed circuit board 1. Retaining washers 7 are pressed onto the free ends of the attachment pins 2. As a result, the printed circuit board 1 is pressed toward the main surface 5a of the lower part 5 of the housing, and movement in the direction of the z-axis is prevented.

The attachment pins 2 are designed such that they also serve as spacers 8. As a result, the printed circuit board 1 does not rest against the main surface 5a of the lower part 5 of the housing, but rather, is disposed at a spacing thereto. The attachment pin 2 is comprised thereby of a lower section, which serves as a spacer 8, and an upper section, which serves as an attachment member and which passes through a corresponding hole 3, 3a in the printed circuit board 1. For practical purposes, the cross-section of the lower section of the attachment pin 2, serving as the spacer 8, is designed such that it cannot pass through a corresponding hole 3a, 3 in the printed circuit board. The transition between the lower section 8 and the upper section forms a collar 8a, on which the printed circuit board 1 rests. The space between the printed circuit board 1 and the lower part 5 of the housing can serve, for example, for the dissipation of heat. Further spacers 8 may be provided, which are not depicted in FIG. 2. These spacers 8 may serve as support, or bearing surfaces, for the printed circuit board 1.

Retaining washers 7 are attached to the upper sections of the attachment pins 2 passing through the holes 3a, 3 in the printed circuit board 1. These retaining washers 7 are pressed substantially toward the printed circuit board 1 starting at the free ends of the attachment pins 2.

### REFERENCE SYMBOLS

1 printed circuit board
2 attachment pin
3 hole having a transition fit for the attachment pin
3a further hole for attachment pins
4 intermediate space
5 lower part of the housing
6 housing cover
7 retaining washer
8 spacer
8a collar
G housing

1. A control device, for a transmission of a vehicle comprising:
a housing including a lower part and a housing cover, wherein the lower part of the housing has an assembly region on a first main surface,
at least one attachment pin disposed in the assembly region, wherein the at least one attachment pin protrudes from the main surface of the lower part of the housing and terminates inside the housing,
a printed circuit board disposed in the assembly region, the printed circuit board having at least one opening corresponding to the at least one attachment pin, wherein the at least one attachment pin passes through the at least one opening, and
at least one retaining washer disposed on the at least one attachment pin and configured to be pressed towards the printed circuit board on the at least one attachment pin to block a movement of the printed circuit board toward a free end of the at least one attachment pin.

2. The control device according to claim 1, wherein the at least one attachment pin includes a first attachment pin and a second attachment pin, wherein the at least one opening includes a first opening and a second opening, wherein the first opening receives the first attachment pin with a transition fit, and wherein the second opening receives the second attachment pin with a clearance fit.

3. The control device according to claim 1, wherein at least one opening in the printed circuit board is elliptical or oval.

4. The control device according to claim 3, wherein the length of a main axis of the at least one opening is greater than the greatest expansion of the at least one retaining washer pressed onto the at least one attachment pin passing through the at least one hole.

5. The control device according to claim 1, wherein the at least one attachment pin comprises a lower section adjacent to the main surface and configured to space the printed circuit board from the main surface.

6. The control device according to claim 5, wherein the at least one attachment pin comprises a collar located adjacent to the lower section and configured to contact the printed circuit board.

7. The control device according to claim 5, wherein the attachment pin comprises an upper section extending from the lower section and configured to pass through at least one opening.

8. The control device according to claim 1, wherein the at least one attachment pin comprises a first attachment pin and a second attachment pin and the at least one opening comprises a first opening and a second opening,
wherein the first attachment pin includes a first cross-section configured to be received by the first opening and the second attachment member includes a second cross-section configured to be received by the second opening,
wherein the first opening is substantially the same size as the second opening, and
wherein the first cross-section is larger than the second cross section.

9. The control device according to claim 7, wherein the cross-section of the lower section of the at least one attachment pin is larger than the cross-section of the upper section of the at least one attachment pin.

10. A control device of a vehicle transmission, the control comprising a housing cover and a lower part, the lower part having a main surface and a first attachment member extending from the main surface, the attachment member comprising:
a first lower portion, the first lower portion having a first cross-section size, the first lower portion being located adjacent to the first surface;
a first upper portion extending from the first lower portion and away from the main surface, wherein the first upper portion has a second cross-section size, and wherein the second cross-section size is smaller than the first cross-section size; and
a first collar located at the junction of the first lower portion and the first upper portion, the collar defining a second surface configured to contact a circuit board.

11. The control device according to claim 10, wherein control device further comprises the circuit board with a first hole receiving the first upper portion.

12. The control device according to claim 10, wherein the lower part includes a second attachment member extending from the main surface, the second attachment member having a second collar defining a third surface configured to contact the circuit board.

13. The control device according to claim 11, wherein the lower part further comprises a second attachment member extending from the main surface and having a second upper portion configured to extend through a second hole of the circuit board.

14. The control device according to claim 12, wherein the second attachment member comprises a second lower portion extending from the main surface and a second upper portion extending from the second lower portion, and wherein the first cross-section size is larger than a cross-section size of the second upper portion.

15. The control device according to claim 13, wherein the first upper portion of the first attachment member extends through the first hole with a transitional fit, and wherein the second upper portion of the second attachment member extends through the second hole with a clearance fit.

16. The control device according to claim 10, wherein the lower part further comprises a space located adjacent to the lower portion of the first attachment member and the main surface.

17. The control device according to claim 12, wherein the lower part further comprises a third attachment member extending from the main surface, the third attachment member having a third collar defining a third surface configured to contact the circuit board.

18. The control device according to claim 10, the control device further comprising at least one retaining washer configured to be pressed towards the main surface on the first attachment pin to block a movement of the circuit board.

19. A control device for a transmission of a vehicle, the control device comprising:
a housing including a lower part and a housing cover, wherein the lower part of the housing has an assembly region on a first main surface,
a first attachment pin disposed in the assembly region, wherein the first attachment pin protrudes from the main surface of the lower part of the housing,
a printed circuit board disposed in the assembly region, the printed circuit board having a first opening corresponding to the first attachment pin, wherein the first attachment pin passes through the first opening to a transitional fit, and
a first one retaining washer disposed on the first attachment pin and configured to be pressed towards the printed circuit board on the first attachment pin to block a movement of the printed circuit board toward a free end of the first attachment pin.

20. The control device according to claim 19, the control device further comprising a second attachment pin disposed in the assembly region, wherein the second attachment pin protrudes from the main surface of the lower part of the housing,
wherein the printed circuit board has a second opening corresponding to the second attachment pin, and wherein the second attachment pin passes through the second opening with a clearance fit.
